(19) United States
(12) Patent Application Publication
(10) Pub. No.: US 2025/0118362 A1
(43) Pub. Date: Apr. 10, 2025

(54) BANKED SENSE AMPLIFIER CIRCUIT FOR A MEMORY CORE AND A MEMORY CORE COMPLEX

(71) Applicant: INTERNATIONAL BUSINESS MACHINES CORPORATION, ARMONK, NY (US)

(72) Inventors: Wolfgang Penth, Holzgerlingen (DE); Jan Niklas Stegmaier, Sindelfingen (DE); Harshawardhan Ramachandran, Boeblingen (DE); Florian Leber, Reutlingen (DE)

(21) Appl. No.: 18/581,069

(22) Filed: Feb. 19, 2024

(30) Foreign Application Priority Data
Oct. 4, 2023 (GB) 2315192.1

(51) Int. Cl. G11C 11/419; G11C 7/08; G11C 7/10; G11C 7/12

(52) U.S. Cl. CPC G11C 11/419; G11C 7/08; G11C 7/1063; G11C 7/12

(57) ABSTRACT

A banked sense amplifier circuit for a memory core complex, being configured to sense at least one local bit line (BL_C) out of local bit lines (BL_C) of two neighboring memory banks out of a plurality of memory banks of the memory core complex to be used as independent read paths, wherein the banked sense amplifier circuit is connected to a global bit line (GBL) of the memory core complex.

### BACKGROUND

The present invention relates in general to data processing systems, in particular, to an sense amplifier circuit for a memory core complex. The invention further relates to a memory core complex.

High performance memories in high performance microprocessors usually comprise static random access memory (SRAM) cells. An SRAM cell is a type of semiconductor memory cell that has low power consumption and fast access time relative to a dynamic random access memory (DRAM) cell. An SRAM cell comprises cross couple inverters and one or more access devices. An inverter has an input and an output having a voltage of opposite polarity to said input. The inverter is connected between a system power voltage level and system ground voltage level.

### SUMMARY

A banked sense amplifier circuit for a memory core complex is proposed, being configured to sense at least one local bit line out of local bit lines of two neighboring memory banks out of a plurality of memory banks of the memory core complex to be used as independent read paths, wherein the banked sense amplifier circuit is connected to a global bit line of the memory core complex.

Further, a memory core complex is proposed, comprising a plurality of memory banks, wherein each memory bank includes a two-dimensional array of memory cells and a memory cell access circuitry; a plurality of local bit lines connecting all memory cells in a first dimension of the two-dimensional array; a plurality of word lines connecting all memory cells in a second dimension of the two-dimensional array; and at least one banked sense amplifier circuit, wherein the banked sense amplifier circuit is connected to a global bit line of the memory core complex.

An array of memory cells is divided into smaller subblocks, the so-called memory banks. A banked array of memory cells is provided with banked sense amplifier circuits as local evaluation circuits. As in the standard ripple domino scheme, just the sense amplifier of the chosen memory bank drives the global bit line, the other sense amplifiers are electrically isolated.

An array of memory cells is divided into smaller subblocks, the so-called memory banks. A banked array of memory cells is provided with banked sense amplifier circuits as local evaluation circuits. As in the standard ripple domino scheme, just the sense amplifier of the chosen memory bank drives the global bit line, the other sense amplifiers are electrically isolated.

### BRIEF DESCRIPTION OF THE SEVERAL VIEWS OF THE DRAWINGS

The present invention together with the above-mentioned and other objects and advantages may best be understood from the following detailed description of the embodiments, but not restricted to the embodiments.

FIG. 1 depicts a general layout of a memory core complex according to an embodiment of the invention.

FIG. 2 depicts a layout of a banked sense amplifier circuit for a memory core complex according to an embodiment of the invention.

### DETAILED DESCRIPTION

In a conventional single-port architecture, each bit in an SRAM cell is stored on four transistors that form two cross-coupled inverters operative as a storage element of the memory cell. Two additional transistors serve to control access to the storage element during read and write operations. A typical SRAM cell uses six transistors.

High performance memories usually comprise array of memory cells, built of six transistor SRAM cells. A cell column can be selected by activating one of the word lines. The cells connected to the chosen word line can be read or written through the connected bit lines.

There are two industry standard ways known to read out an array of memory cells, the so-called ripple domino and the sense amplifier approach. In each case, the cell is driving the bit line connected to it or gets written by the same lines.

If an SRAM cell is not able to fully discharge the large capacitance of the bit line within a cycle the sense amplifier approach could be chosen. In this case, the sense amplifier will detect its value by sensing the voltage difference of a bit line true and a bit line complement. As all bit lines are occupied by a read or write action, it is not possible to read and write the array in the same cycle. The sense amplifier approach could as well be chosen when the cell is strong enough to discharge the capacitance in a single cycle.

With the ripple domino approach array entities with a reduced number of word lines, so called banks, are used. The local read enable signals, a one hot bus, marks the bank to be read in the given cycle. The local evaluation circuit of the selected bank drives the global bit line to the read value, other local evaluation circuits stay electrically isolated from the global bit line. This scheme enables read and write in different banks of the same array in the same cycle.

A random access memory array may include a plurality of local memory group ways, each local memory group way including, a plurality of local memory groups, each local memory group including, a memory column including a plurality of memory cells, a pair of local bit lines operatively connected to the plurality of memory cells, and a local group periphery including a local bit line multiplexer operatively connected with the pairs of local bit lines of the corresponding local memory group; and a pair of global read bit lines operatively connected to outputs of the plurality of local group peripheries; a global read bit line multiplexer operatively connected to outputs of the plurality of pairs of the global read bit lines from the local memory group ways; and a bit line operational block operatively connected to an output of the global read bit line multiplexer, the bit line operational block configured to perform at least one of a logic or arithmetic operation.

A banked sense amplifier circuit for a memory core complex is proposed, being configured to sense at least one local bit line out of local bit lines of two neighboring memory banks out of a plurality of memory banks of the memory core complex to be used as independent read paths, wherein the banked sense amplifier circuit is connected to a global bit line of the memory core complex.

Advantageously, with the proposed banked sense amplifier circuit it is possible to read memory cells of the memory core complex in a way that combines advantages of the two industry standards of a memory read, the sense amplifier approach and the ripple domino approach.

Favourably, the proposed banked sense amplifier circuit overcomes the limitations of technologies. Bit lines get fully discharged in each condition and thus the low voltage performance and low voltage operation of an array is enhanced.

Due to the proposed banked sense amplifier approach reading and writing processes of different memory banks in the same cycle is possible.

The banked sense amplifier circuit enables low power functionality. Combination with the memory bank structure gives high flexibility due to simultaneous read and write actions.

The banked sense amplifier circuit combines two main advantages to the current state of the art. By dividing the array of memory cells into the memory banks, it enables by that read and write of the array in different memory banks in the same cycle and recombines the read result of the memory banks with a big dynamic or on the global bit line. This is usually the advantage of ripple domino.

Further, the banked sense amplifier circuit reads the array with a sense amplifier, which allows lower voltage, weaker cells and improves the performance.

Dynamically combining the output of the sense amplifiers along the global bit line strengthens the performance advantage of the banked sense amplifier circuit, as the connected local bit lines are short while the subsequent logic is very fast.

In an additional or alternative embodiment of the invention, the banked sense amplifier circuit may be configured to sense at least one local bit line pair out of local bit line pairs of two neighboring memory banks out of the plurality of memory banks of the memory core complex to be used as independent read paths, wherein the banked sense amplifier circuit is connected to a global bit line of the memory core complex. Thus the two neighboring memory banks may advantageously be addressed for reading.

In an additional or alternative embodiment of the invention, ports for one bit line of the bit line pair may be used as additional read ports. This may be an advantageous embodiment if only one of two memory banks should be sensed.

Further, a memory core complex is proposed, comprising a plurality of memory banks, wherein each memory bank includes a two-dimensional array of memory cells and a memory cell access circuitry; a plurality of local bit lines connecting all memory cells in a first dimension of the two-dimensional array; a plurality of word lines connecting all memory cells in a second dimension of the two-dimensional array; and at least one banked sense amplifier circuit, wherein the banked sense amplifier circuit is connected to a global bit line of the memory core complex.

Advantageously, with the proposed memory core complex it is able to read memory cells in a way that combines advantages of the two industry standards of a memory read, the sense amplifier approach and the ripple domino approach.

For instance, columns of the array may extend into the first dimension of the array and rows of the array may extend into the second dimension of the array, or vice versa.

The proposed memory core complex overcomes the limitations of technologies. Bit lines get fully discharged in each condition and thus the low voltage performance and low voltage operation of an array is enhanced.

Due to the proposed banked sense amplifier approach reading and writing processes of different memory banks in the same cycle is possible.

The ability to drive both data values, i.e., high and low, provides the advantage that no keeper circuit is needed on the global bit line to compensate for leakage. Feeding a single banked sense amplifier circuit with the local bit lines of two memory banks instead of one sense amplifier per memory bank reduces the area required for the devices and thus results in an area advantage on the memory core complex. The single ended global bit line wire has the advantage of needing fewer wire resources.

The banked sense amplifier circuit enables low power functionality. Combination with the memory bank structure gives high flexibility due to simultaneous read and write actions.

The combination of a banked sense amplifier circuit with the memory bank structure gives high flexibility due to simultaneous read and write actions.

An array of memory cells is divided into smaller subblocks, the so-called memory banks. A banked array of memory cells is provided with banked sense amplifier circuits as local evaluation circuits. As in the standard ripple domino scheme, just the sense amplifier of the chosen memory bank drives the global bit line, the other sense amplifiers are electrically isolated.

This design allows the banked operation of reads and writes in the same cycle, while it significantly lowers the potential operation voltage of the array and increases its performance at a given voltage.

The banked sense amplifier circuit combines two main advantages to the current state of the art. By dividing the array of memory cells into the memory banks, it enables by that read and write of the array in different memory banks in the same cycle and recombines the read result of the memory banks with a big dynamic or on the global bit line. This is usually the advantage of ripple domino.

Further, the banked sense amplifier circuit reads the array with a sense amplifier, which allows lower voltage operation, weaker cells and improves the performance.

Dynamically combining the output of the sense amplifiers along the global bit line strengthens the performance advantage of the banked sense amplifier circuit, as the connected local bit lines are short while the subsequent logic is very fast.

Advantageously, the memory cells may be static random access memory (SRAM) cells. An SRAM cell has low power consumption and fast access time. High performance memories in high performance microprocessors are widely comprising SRAM cells.

In an additional or alternative embodiment of the invention, the banked sense amplifier circuit may be configured to sense at least one local bit line out of the local bit lines of two neighboring memory banks out of the plurality of memory banks to be used as independent read paths. Thus individual memory banks may advantageously be addressed for reading.

In an additional or alternative embodiment of the invention, the banked sense amplifier circuit may be configured to sense at least one local bit line pair out of local bit line pairs of two neighboring memory banks out of the plurality of memory banks to be used as independent read paths. Thus the two neighboring memory banks may advantageously be addressed for reading.

In an additional or alternative embodiment of the invention, at least one multiplexer may be provided in the at least one memory bank per the first dimension associated with local bit lines of two neighboring memory banks out of the plurality of memory banks. Multiplexers may advantageously be used for addressing the memory cells.

In an additional or alternative embodiment of the invention, the banked sense amplifier circuit may be logically located between the at least one multiplexer and the global bit line. Thus the local bit line may be chosen by the multiplexer and transferred to the banked sense amplifier circuit.

In an additional or alternative embodiment of the invention, the at least one multiplexer may be configured to transfer the local bit lines to the banked sense amplifier circuit. In particular, the transfer of the local bit lines to the banked sense amplifier circuit may be driven by a local read enable line. Thus, addressing the local bit line for the reading process advantageously may be achieved.

In an additional or alternative embodiment of the invention, an input/output device may be provided comprising output drivers for transferring the global bit lines to output lines. Thus, stable output signals may result.

In an additional or alternative embodiment of the invention, in the banked sense amplifier circuit ports of bit lines not used for the sensing process may be configured as additional read ports. This may be an advantageous embodiment if only one of the two memory banks should be sensed.

In an additional or alternative embodiment of the invention, two memory banks out of the plurality of memory banks may be arranged in a double memory bank. Thus, state of the art layouts of memory core may advantageously be used to be modified according to the proposed memory core complex using assist cells for read/write processes.

In an additional or alternative embodiment of the invention, at least one multiplexer may be provided in the double memory bank per the first dimension associated with at least one local bit line of each of two neighboring memory banks in the double memory bank. Multiplexers may advantageously be used for addressing the memory cells.

Further, a memory core complex is proposed, comprising a plurality of double memory banks, wherein each double memory bank comprises two memory banks, wherein each memory bank includes a two-dimensional array of memory cells and a memory cell access circuitry; a plurality of local bit lines connecting all memory cells in a first dimension of the two-dimensional array; a plurality of word lines connecting all memory cells in a second dimension of the two-dimensional array; and at least one banked sense amplifier circuit, wherein the banked sense amplifier circuit is connected to a global bit line of the memory core complex.

Advantageously, with the proposed memory core complex it is able to read memory cells in a way that combines advantages of the two industry standards of a memory read, the sense amplifier approach and the ripple domino approach.

The proposed memory core complex overcomes the limitations of technologies. Bit lines get fully discharged in each condition and thus the low voltage performance and even low voltage operation of an array is enhanced.

Due to the proposed banked sense amplifier approach reading and writing processes of different double memory banks in the same cycle is possible. Favourably, the proposed banked sense amplifier circuit overcomes the limitations of technologies.

An array of memory cells is divided into smaller subblocks, the so-called memory banks. A banked array of memory cells is provided with banked sense amplifier circuits as local evaluation circuits. As in the standard ripple domino scheme, just the sense amplifier of the chosen memory bank drives the global bit line, the other sense amplifiers are electrically isolated.

This design allows the banked operation of reads and writes in the same cycle, while it significantly lowers the potential operation voltage of the array and increases its performance at a given voltage.

The banked sense amplifier circuit combines two main advantages to the current state of the art. By dividing the array of memory cells into the memory banks, it enables by that read and write of the array in different memory banks in the same cycle and recombines the read result of the memory banks with a big dynamic or on the global bit line. This is usually the advantage of ripple domino.

Further, the banked sense amplifier circuit reads the array with a sense amplifier, which allows lower voltage, weaker cells and improves the performance.

Dynamically combining the output of the sense amplifiers along the global bit line strengthens the performance advantage of the banked sense amplifier circuit, as the connected local bit lines are short while the subsequent logic is very fast.

Advantageously, the memory cells may be static random access memory (SRAM) cells. An SRAM cell has low power consumption and fast access time. High performance memories in high performance microprocessors are widely comprising SRAM cells.

In an additional or alternative embodiment of the invention, the banked sense amplifier circuit may be configured to sense at least one local bit line pair out of local bit line pairs of two neighboring memory banks out of the plurality of memory banks to be used as independent read paths. Thus the two neighboring memory banks may advantageously be addressed for reading.

In an additional or alternative embodiment of the invention, at least one multiplexer may be provided in the at least one memory bank per the first dimension associated with local bit lines of two neighboring memory banks out of the plurality of memory banks. Multiplexers may advantageously be used for addressing the memory cells.

In an additional or alternative embodiment of the invention, the banked sense amplifier circuit may be logically located between the at least one multiplexer and the global bit line. Thus the local bit line may be chosen by the multiplexer and transferred to the banked sense amplifier circuit.

In an additional or alternative embodiment of the invention, the at least one multiplexer may be configured to transfer the local bit lines to the banked sense amplifier circuit. In particular, the transfer of the local bit lines to the banked sense amplifier circuit may be driven by a local read enable line. Thus, addressing the local bit line for the reading process advantageously may be achieved.

In an additional or alternative embodiment of the invention, an input/output device may be provided comprising output drivers for transferring the global bit lines to output lines. Thus, stable output signals may result.

In an additional or alternative embodiment of the invention, in the banked sense amplifier circuit ports of bit lines not used for the sensing process may be configured as additional read ports. This may be an advantageous embodiment if only one of the two memory banks should be sensed.

In the drawings, like elements are referred to with equal reference numerals. The drawings are merely schematic representations, not intended to portray specific parameters of the invention. Moreover, the drawings are intended to depict only typical embodiments of the invention and therefore should not be considered as limiting the scope of the invention.

The illustrative embodiments described herein provide a banked sense amplifier circuit for a memory core complex, being configured to sense at least one local bit line out of local bit lines of two neighboring memory banks out of a plurality of memory banks of the memory core complex to be used as independent read paths, wherein the banked sense amplifier circuit is connected to a global bit line of the memory core complex.

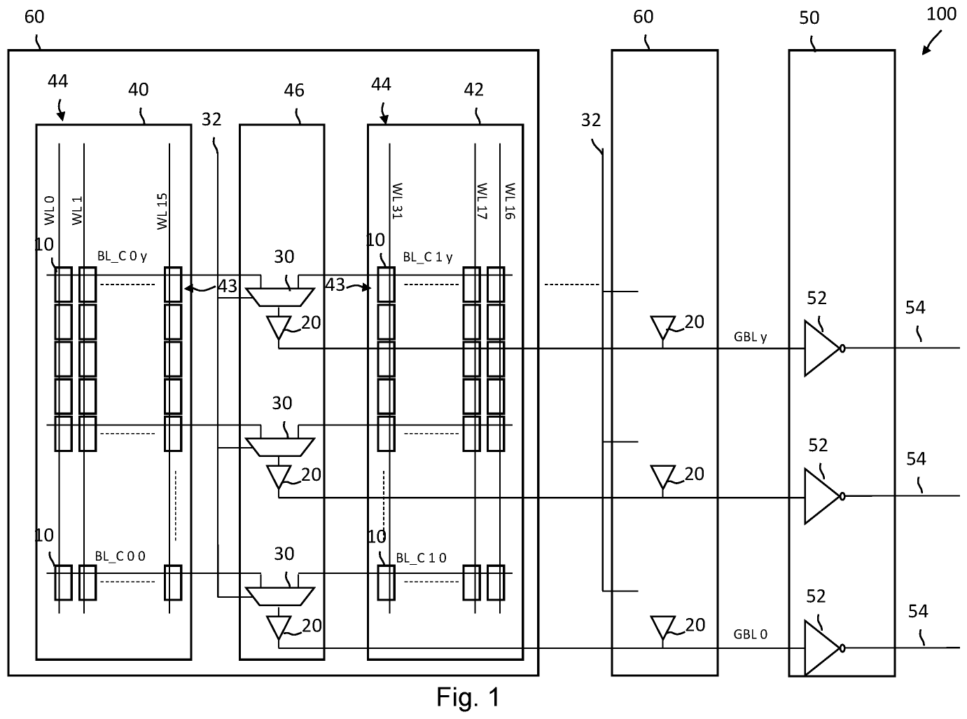

FIG. 1 depicts a general layout of a memory core complex according to an embodiment of the invention.

The memory core complex 100 in FIG. 1 comprises a plurality of memory banks 40, 42, wherein each memory bank 40, 42 includes a two-dimensional array of memory cells 10 and a memory cell access circuitry 46. The memory cells 10 are static random access memory cells.

The memory bank 40 comprises a number of sixteen memory cells 10 arranged in rows corresponding to a first dimension 43 of the two-dimensional array, numbered 0 to 15, and a number of y+1 memory cells 10 arranged in columns corresponding to a second dimension 44 of the two-dimensional array. The memory bank 42 has the same size. The memory cells 10 of the first dimension 43 are numbered 16 to 31.

A plurality of local bit lines BL_C00 to BL_C0y, BL_C10 to BL_C1y, respectively, is connecting all memory cells 10 in the first dimension 43 of the two-dimensional array, whereas a plurality of word lines WL0 to WL15, and WL16 to WL31, respectively, is connecting all memory cells 10 in the second dimension 44 of the two-dimensional array.

The memory cell access circuitry 46 comprises multiplexers 30. At least one multiplexer 30 is provided in the at least one memory bank 40, 42 per the first dimension 43 associated with at least one local bit line BL_C of one of the memory banks 40, 42 out of the plurality of memory banks 40, 42. In the embodiment shown the multiplexers 30 are connected to a local bit line BL_C of each of the two neighboring memory banks 40, 42.

The memory cell access circuitry 46 also comprises banked sense amplifier circuits 20, wherein a banked sense amplifier circuit 20 is connected to a multiplexer 30 and to a global bit line GBL. Thus, the banked sense amplifier circuit 20 is logically located between the at least one multiplexer 30 and the global bit line GBL.

The banked sense amplifier circuits 20 are configured to sense at least one local bit line BL_T, BL_C out of local bit lines BL_T, BL_C of two neighboring memory banks 40, 42 out of the plurality of memory banks 40, 42 to be used as independent read paths. In the embodiment shown the banked sense amplifier circuits 20 sense the local bit line BL_C of one of the memory banks 40, 42 which is triggered by the local read enable line 32.

The multiplexers 30 transfer the local bit lines BL_C00 to BL_C0y, BL_C10 to BL_C1y, respectively, to the banked sense amplifier circuit 20. In particular, the transfer of the local bit lines BL_C to the banked sense amplifier circuit 20 is driven by a local read enable line 32. Thus, the banked sense amplifier circuit 20 may serve for amplification of the content of the local bit line BL_C and transfer to the global bit line GBL.

In a favourable embodiment (not shown), the banked sense amplifier circuits 20 may be configured to sense at least one local bit line pair BL_T, BL_C out of local bit line pairs BL_T, BL_C of two neighboring memory banks 40, 42 out of the plurality of memory banks 40, 42 to be used as independent read paths.

An input/output device 50 is provided comprising output drivers 52 for transferring the global bit lines GBL0 to GBLy to output lines 54.

In the embodiment shown in FIG. 1 two memory banks 40, 42 are arranged in one double memory bank 60. The double memory bank 60 comprises one memory cell access circuitry 46 serving both memory banks 40, 42.

The second double memory bank 60 is depicted with the banked sense amplifier circuits 20 only for simplification of the Figure. It is to be understood, that this double memory bank 60 also comprises two memory banks 40, 42 and the whole memory cell access circuitry 46. In the double memory bank 60 at least one multiplexer 30 is provided per the first dimension 43 associated with at least one local bit line BL_C of each of two neighboring memory banks 40, 42 in the double memory bank 60.

Thus, the embodiment of FIG. 1 depicts double memory banks 60 with two memory banks 40, 42 each of memory cells 10 with banked sense amplifier circuits 20 as local evaluation circuits. The local read enable signal 32 marks the memory bank 40, 42 to be read in the given cycle. As in the standard ripple domino scheme, just the banked sense amplifier circuits 20 of the chosen memory bank 40, 42 drives the global bit line GBL, the other banked sense amplifier circuits 20 are electrically isolated.

This design allows the banked operation of reads and writes in the same cycle, while it significantly lowers the potential operation voltage of the memory bank 40, 42 and increases its performance at a given voltage.

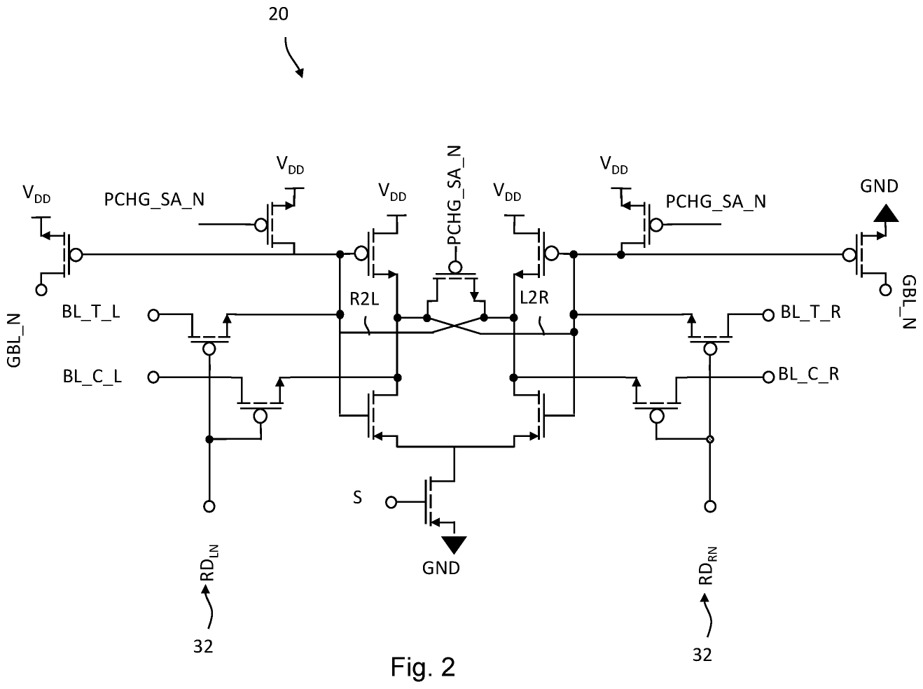

FIG. 2 depicts a layout of a banked sense amplifier circuit 20 for a memory core complex 100 according to an embodiment of the invention. The banked sense amplifier circuit 20 may correspond to one of the banked sense amplifier circuits 20 used in the embodiment shown in FIG. 1 for amplification of the content of the local bit line BL_C and transfer to the global bit line GBL.

The banked sense amplifier circuit 20 is provided with local bit lines BL_T_L, BL_T_R, BL_C_L, BL_C_R as well as local bit lines BL_C_L, BL_C_R as an input and the global bit line GBL_N as an output.

For using the banked sense amplifier circuit 20 in the memory core complex 100 shown in FIG. 1, the local bit lines BL_C_L, BL_C_R may only be used, connected to the local bit lines BL_C of the memory core complex 100 and the local read enable signals RDLN, RDRN may be connected to the local read enable lines 32.

A further input to the banked sense amplifier circuit 20 is the sense signal S which is provided on a cycle basis from a processor. Further input for controlling the functions of the banked sense amplifier circuit 20 is the precharge signal PCHG_SA_N.

According to principle functioning of a sense amplifier, the banked sense amplifier circuit 20 gets precharged in each cycle (PCHG_SA_N goes to 0). In the evaluation phase, the precharge stops (PCHG_SA_N goes to 1) and the local bit lines BL_T_L, BL_T_R, BL_C_L, BL_C_R get driven by the banked sense amplifier circuit 20. After the necessary setup time for the local bit lines BL_T_L, BL_T_R, BL_C_L, BL_C_R, the sense amplification starts by pulling the banked sense amplifier circuit internal nodes R2L, L2R to 1.

Thus, at the end of each cycle, local bit lines BL_T_L, BL_T_R, BL_C_L, BL_C_R and banked sense amplifier circuit internal nodes R2L, L2R are precharged. This means signal PCHG_SA_N is low. Local bit line precharge is not shown. The global bit line GBL_N is discharged. At the start of a read cycle, the precharge ends, which means the signal PCHG_SA_N is high, local bit line precharge and global bit line discharge end as well.

If the memory bank 40, 42 (see FIG. 1) on its side should be read in the given cycle, the local read enable line 32 gets active (=0). Only one of all local read enable lines 32 can be active in the given cycle.

The read cycle starts with setting a word line WL (see FIG. 1) high. The connected memory cells 10 of the memory core complex 100 in FIG. 1 will start pulling down the bit lines BL_T or BL_C, depending on their data content.

The local read enable signals RD_{LN}, RD_{RN} which is connected with the local read enable lines 32 of the memory core complex 100 in FIG. 1 gets active (=low). This connects the local bit lines BL_T_L, BL_T_R, BL_C_L, BL_C_R of the chosen side of the memory core complex 100 with the internal nodes R2L, L2R of the banked sense amplifier circuit 20, driving them to the same voltage as the bit lines BL_T_L, BL_T_R, BL_C_L, BL_C_R.

When the voltage difference between the internal nodes R2L and L2R is big enough, the amplification can start. Setting the sense signal S high starts the amplification of the voltage difference between the internal nodes R2L and L2R, driving one of the internal nodes R2L and L2R entirely low while keeping the other high. This will drive the global bit line GBL_N to the inverted value of the content of the corresponding memory cell 10 of the memory core complex 100 in FIG. 1.

So, the firing sense signal S (=1) starts the amplification of the content of the local bit line BL_T_L, BL_T_R, BL_C_L, BL_C_R, driving actively one of the internal nodes R2L and L2R.

In an alternative embodiment, it would also be possible to sense just one side, BL_C or BL_T. In that case, the different sides of the banked sense amplifier circuit 20 could be used for different read ports.

1. A banked sense amplifier circuit for a memory core complex, being configured to sense at least one local bit line (BL_C) out of local bit lines (BL_C) of two neighboring memory banks out of a plurality of memory banks of the memory core complex to be used as independent read paths, wherein the banked sense amplifier circuit is connected to a global bit line (GBL) of the memory core complex.

2. The banked sense amplifier circuit according to claim 1, being configured to sense at least one local bit line pair (BL_T, BL_C) out of local bit line pairs (BL_T, BL_C) of two neighboring memory banks out of the plurality of memory banks of the memory core complex to be used as independent read paths, wherein the banked sense amplifier circuit is connected to a global bit line (GBL) of the memory core complex.

3. The banked sense amplifier circuit according to claim 2, wherein ports for one bit line (BL_T, BL_C) of the bit line pair (BL_T, BL_C) are used as additional read ports.

4. A memory core complex comprising:
a plurality of memory banks, wherein each memory bank includes a two-dimensional array of memory cells and a memory cell access circuitry;
a plurality of local bit lines (BL_C) connecting all memory cells in a first dimension of the two-dimensional array;
a plurality of word lines (WL) connecting all memory cells in a second dimension of the two-dimensional array; and
at least one banked sense amplifier circuit, wherein the banked sense amplifier circuit is connected to a global bit line (GBL) of the memory core complex.

5. The memory core complex according to claim 4, wherein the banked sense amplifier circuit is configured to sense at least one local bit line (BL_C) out of the local bit lines (BL_C) of two neighboring memory banks out of the plurality of memory banks to be used as independent read paths.

6. The memory core complex according to claim 4, wherein the banked sense amplifier is configured to sense at least one local bit line pair (BL_T, BL_C) out of local bit line pairs (BL_T, BL_C) of two neighboring memory banks out of the plurality of memory banks to be used as independent read paths.

7. The memory core complex according to claim 4, wherein at least one multiplexer is provided in the at least one memory bank per the first dimension associated with local bit lines (BL_C) of two neighboring memory banks out of the plurality of memory banks.

8. The memory core complex according to claim 7, wherein the banked sense amplifier circuit is logically located between the at least one multiplexer and the global bit line (GBL).

9. The memory core complex according to claim 7, wherein the at least one multiplexer is configured to transfer the local bit lines (BL_C) to the banked sense amplifier circuit,
wherein the transfer of the local bit lines (BL_C) to the banked sense amplifier circuit is driven by a local read enable line.

10. The memory core complex according to claim 4, wherein an input/output device is provided comprising output drivers for transferring the global bit lines (GBL) to output lines.

11. The memory core complex according to claim 5, wherein in the banked sense amplifier circuit ports of bit lines (BL_T, BL_C) not used for the sensing process are configured as additional read ports.

12. The memory core complex according to claim 4, wherein two memory banks out of the plurality of memory banks are arranged in a double memory bank.

13. The memory core complex according to claim 12, wherein at least one multiplexer is provided in the double memory bank per the first dimension associated with at least one local bit line (BL_C) of each of two neighboring memory banks in the double memory bank.

14. A memory core complex comprising:
a plurality of double memory banks, wherein each double memory bank comprises two memory banks, wherein each memory bank includes a two-dimensional array of memory cells and a memory cell access circuitry;
a plurality of local bit lines (BL_C) connecting all memory cells in a first dimension of the two-dimensional array;
a plurality of word lines (WL) connecting all memory cells in a second dimension of the two-dimensional array; and
a banked sense amplifier circuit, wherein the banked sense amplifier circuit is connected to a global bit line (GBL) of the memory core complex.

15. The memory core complex according to claim 14, wherein the banked sense amplifier circuit is configured to sense at least one local bit line-pair (BL_T, BL_C) out of local bit line-pairs (BL_T, BL_C) of two neighboring memory banks out of the plurality of memory banks to be used as independent read paths.

16. The memory core complex according to claim 14, wherein at least one multiplexer is provided in the at least one memory bank per the first dimension associated with local bit lines (BL) of two neighboring memory banks out of the plurality of memory banks.

17. The memory core complex according to claim 16, wherein the banked sense amplifier circuit is logically located between the at least one multiplexer and the global bit line (GBL).

18. The memory core complex according to claim 16, wherein the at least one multiplexer is configured to transfer the local bit lines (BL_C) to the banked sense amplifier circuit,
wherein the transfer of the local bit lines (BL_C) to the banked sense amplifier circuit is driven by a local read enable line.

19. The memory core complex according to claim 14, wherein an input/output device is provided comprising output drivers for transferring the global bit lines (GBL) to output lines.

20. The memory core complex according to claim 15, wherein in the banked sense amplifier circuit ports of bit lines (BL_T, BL_C) not used for the sensing process are configured as additional read ports.
